(19) United States
(12) Patent Application Publication
(10) Pub. No.: US 2026/0316173 A1
(43) Pub. Date: Oct. 15, 2026

(54) BONDING APPARATUS

(71) Applicant: SHIBUYA CORPORATION, Kanazawa-shi (JP)

(72) Inventor: Masato KITAGAWA, Kanazawa-shi (JP)

(21) Appl. No.: 19/643,192

(22) Filed: Apr. 9, 2026

(30) Foreign Application Priority Data
Apr. 11, 2025 (JP) 2025-065488

(51) Int. Cl. B23K 3/047; B23K 1/00; B23K 1/005; B23K 3/08; B23K 101/40; H10W 72/00

(52) U.S. Cl. CPC B23K 3/0478; B23K 1/0016; B23K 1/0056; B23K 3/087; H10W 72/07141; B23K 2101/40

(57) ABSTRACT

A bonding apparatus that includes a laser light irradiation unit that emits laser light, a holding unit that holds a chip, and a light guiding unit that guides the laser light to a top surface of the chip, held by the above-described holding unit. The laser light irradiation unit has a first laser oscillator that emits a first laser light set to output power that does not melt bumps formed on the chip, and a second laser oscillator that emits a second laser light. A control unit causes the first laser oscillator to emit the first laser light to preheat the chip, and thereafter causes the second laser oscillator to emit the second laser light, to the above-described chip to a bondable temperature.

### BACKGROUND OF THE INVENTION

### Field of the Invention

The present invention relates to a bonding apparatus, and particularly relates to a bonding apparatus that heats a chip with laser light when bonding the chip to a substrate.

### Description of the Related Art

Conventionally, a bonding apparatus has been known that includes laser light irradiation unit that emits laser light, holding unit that holds a chip, and light guiding unit that guides the above-described laser light to the top surface of the chip held by the holding unit.

A plurality of bumps made of solder are formed on the back surface of the above-described chip, the above-described chip is heated with laser light to melt the bumps, and in this state, the chip and a substrate are brought into close contact with each other and bonded (Japanese Laid-Open Patent Application No. 2024-88234).

Here, in order to perform bonding efficiently, it is necessary to quickly heat the chip to melt the bumps, and in recent years, since it has become necessary to bond large chips, laser light with high power has come to be used.

On the other hand, in order to accurately bond the chip and a substrate, it is desirable to preheat the chip and align it with the substrate in a state in which the chip is thermally expanded, but it is difficult to finely adjust the output power of a laser oscillator with high power, and there was a problem in that it was not possible to stably maintain a temperature (about 140° C. to 180° C.) that would not melt the bumps formed on the chip.

In view of the problem as above, the present invention provides a bonding apparatus that can bond chips to substrates more efficiently and accurately.

### SUMMARY OF THE INVENTION

A bonding apparatus according to the invention of claim 1 comprising: a laser light irradiation unit that emits laser light; a holding unit that holds a chip in which a bump is formed on an undersurface; and a light guiding unit that guides the laser light to a top surface of the chip held by the holding unit,
wherein the laser light irradiation unit has a first laser oscillator that emits a first laser light set to output power that does not melt the bump, and a second laser oscillator that emits a second laser light set to higher output power than the first laser light, and includes a control unit that controls the first laser oscillator and the second laser oscillator, and
wherein the control unit is configured to cause the first laser oscillator to emit the first laser light to preheat the chip, and thereafter cause the second laser oscillator to emit the second laser light, or cause the first and second laser oscillators to emit the first laser light and the second laser light, so as to heat the chip to a bondable temperature.

According to the above-described invention, by firstly irradiating the chip with the first laser light of the first laser oscillator and heating it to a degree that does not melt the bump, the chip can be preheated, and the chip can also be thermally expanded for alignment.

Thereafter, by irradiating the chip with the second laser light, or the first laser light and the second laser light, the chip is bonded to the substrate, and at this time, since the chip is already heated to a predetermined temperature, the chip can be quickly heated to the bondable temperature, which enables efficient bonding.

### BRIEF DESCRIPTION OF THE DRAWINGS

FIG. 1 is a sectional view of a bonding apparatus according to the present embodiment;

FIG. 2 is a plan view of holding unit;

FIG. 3 is a view explaining light guiding unit; and

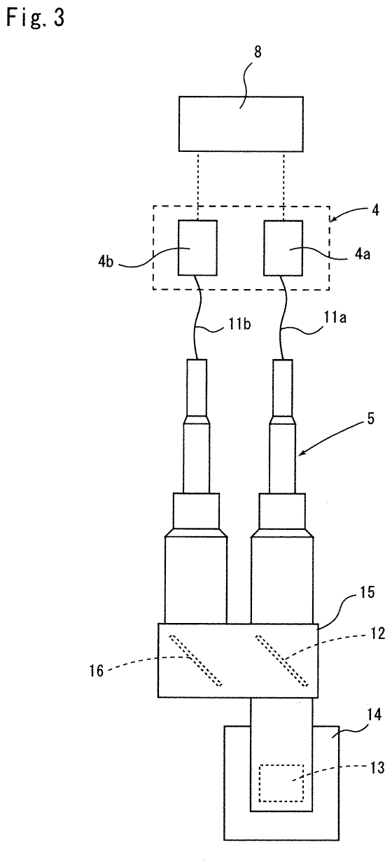

FIG. 4 is a view explaining an operation of the light guiding unit.

### DETAILED DESCRIPTION OF THE INVENTION

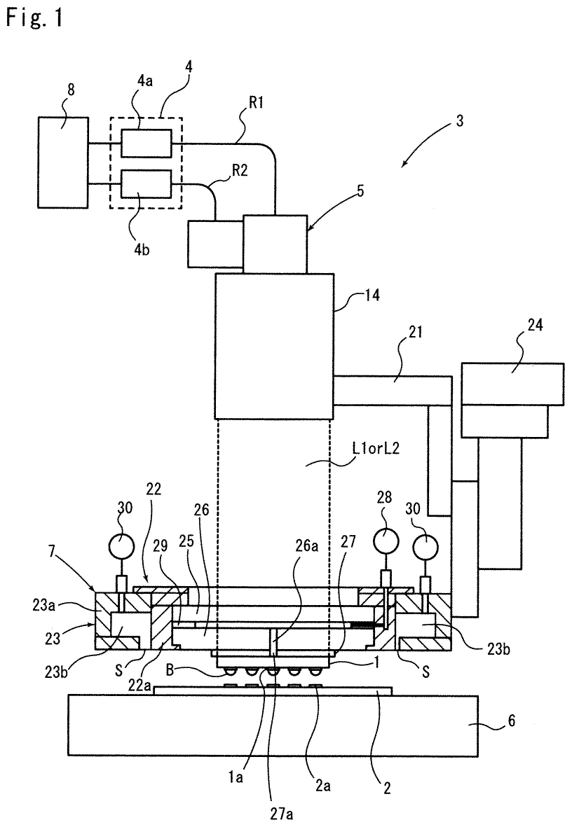

Describing an illustrated embodiment hereinafter, FIG. 1 shows a bonding apparatus 3 that bonds a chip 1 such as a semiconductor chip to a substrate 2.

The above-described bonding apparatus 3 includes laser light irradiation unit 4 that emits laser light L, light guiding unit 5 that guides the above-described laser light L, a bonding stage 6 that supports the substrate 2, and a bonding head 7 that holds the above-described chip 1, and these are controlled by control unit 8 made up of a computer or the like.

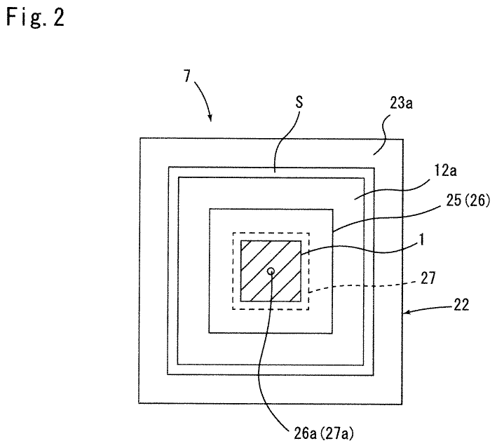

The above-described chip 1 has a substantially square shape as shown in FIG. 2, a plurality of electrodes 1a are provided on a back surface of the chip 1 as shown in FIG. 1, and a bump B made of solder is formed at each of the electrodes 1a.

The above-described substrate 2 is formed to be larger than the above-described chip 1, and electrodes 2a are provided at required positions on a front surface of the substrate 2, in same arrangement as the electrodes la of the above-described chip 1.

Here, the bonding apparatus 3 of the present embodiment can bond the large chip 1 of approximately 75 mm on each side, to the substrate 2.

The above-described bonding stage 6 includes suction unit not illustrated and can suck and hold the substrate 2 on a top surface thereof. Note that an X-Y table that moves the bonding stage 6 in a horizontal direction may be included.

Further, the bonding stage 6 of the present embodiment has heating unit not illustrated and makes it possible to bond the chip 1 to the substrate 2 that is heated to a required temperature.

Accordingly, the held substrate 2 is in a state of being thermally expanded by heating, and the positions of the electrodes 2a formed on the substrate 2 are slightly changed as compared with those before heating.

The above-described laser light irradiation unit 4 includes a first laser oscillator 4a that emits a first laser light L1, and a second laser oscillator 4b that emits a second laser light L2, and the first laser oscillator 4a and the second laser oscillator 4b can be individually controlled by the above-described control unit 8.

The first laser light L1 emitted by the above-described first laser oscillator 4a is suitable for preheating the chip 1, and heats the entire chip 1, but only heats it to a temperature that does not melt the bumps B formed on the chip 1. For example, the output power of the first laser light L1 can be set to 100 to 150 W.

On the other hand, the above-described laser oscillator 4b emits the second laser light L2 having higher output power than the above-described first laser light L1, and heats the above-described chip 1 to a temperature suitable for bonding it to the substrate 2, that is, a temperature that melts the above-described bumps B. For example, the output power of the second laser light L2 can be set to 300 to 600 W.

Furthermore, in the present embodiment, a wavelength of the first laser light L1 and a wavelength of the second laser light L2 are made different, and the wavelength of the first laser light is 930 nm, whereas the wavelength of the second laser light L2 is 975 to 995 nm. Note that the above-described wavelengths can be properly set according to a material and a heating process of the chip 1.

The light guiding unit 5 of the present embodiment is configured to form a first light guide path R1 that guides the first laser light L1 emitted from the first laser oscillator 4a to the above-described bonding head 7, and a second light guide path R2 that guides the second laser light L2 emitted by the second laser oscillator 4b to the above-described bonding head 7.

In the above-described first guide path R1, a first optical fiber 11a connected to the above-described first laser oscillator 4a, a half mirror 12 that transmits the first laser light L1 emitted from the first optical fiber 11a, a mirror 13 that reflects the first laser light L1 that has passed through the half mirror 12, and an optical component 14 that shapes the above-described first laser light L1.

An end portion of the above-described first optical fiber 11a is connected to a housing 15 in which the above-described half mirror 12 and mirror 13 are accommodated, and the above-described half mirror 12 is provided on an optical axis of the first laser light L1 emitted from the end portion of the first optical fiber 11a.

The above-described half mirror 12 is coated with a dielectric multilayer film and is configured to transmit light of the wavelength set to the above-described first laser light L1 and reflect light of the wavelength set to the second laser light L2.

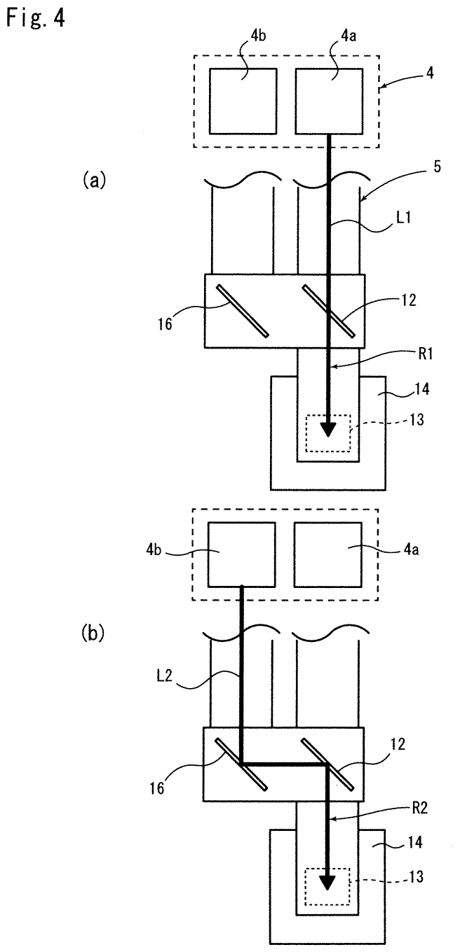

With this configuration, as shown in FIG. 4(a), the above-described first light guide path R1 guides the first laser light L1 emitted by the above-described first laser oscillator 4a by the above-described first optical fiber 11a, causes the first laser light L1 to pass through the above-described half mirror 12, and further reflects it toward the above-described optical component 14 by the above-described mirror 13 to thereby guide it to the top surface of the chip 1 held by the bonding head 7.

On the other hand, in the above-described second light guide path R2, a second optical fiber 11b connected to the above-described second laser oscillator 4b, and a second mirror 16 that reflects the second laser light L2 that is emitted from the second optical fiber 11b, toward the above-described half mirror 12.

An end portion of the above-described second optical fiber 11b is connected to the above-described housing 15, and the second mirror 16 is provided on an optical axis of the second laser light L2 that is emitted from the end portion of the second optical fiber 11b, and is provided to reflect the second laser light L2 toward the above-described half mirror 12.

As described above, the above-described half mirror 12 is configured to reflect the second laser light L2, and an angle of the above-described second mirror 16 and the above-described half mirror 12 is set so that the second laser light L2 reflected from these mirrors is coaxial with the first light guide path R1 of the first laser light L1 that passes through the above-described half mirror 12.

Accordingly, as shown in FIG. 4(b), after the above-described second light guide path R2 guides the second laser light L2 emitted by the above-described second laser oscillator 4b by the above-described second optical fiber 11b, it causes the second laser light L2 to be reflected by the second mirror 16 and the above-described half mirror 12, further causes the second laser light L2 to be reflected toward the above-described optical component 14 by the above-described mirror 13, and thereby guides the second laser light L2 to the top surface of the chip 1 held by the above-described bonding head 7.

The above-described optical component 14 is fixed above the bonding head 7 via a holding member 21, and is composed of a homogenizer, an expander, a collimator, and the like.

According to the above-described optical component 14, it is designed to adjust the laser lights to parallel lights and then emit them toward the bonding head 7, when the above-described first and second laser lights L1 and L2 pass through it. Note that a beam shaper may be contained in the above-described optical component 14, and may shape an output shape (beam profile) of the laser light L to a top hat shape.

The adjusted laser light L is set to a rectangular shape (approximately 70 mm square) with which the entire top surface of the above-described chip 1 is irradiated, and a whole of the large chip 1 held by the bonding head 7 is irradiated with the laser light L.

The above-described bonding head 7 includes the above-described holding member 21 that holds the optical component 14 of the above-described light guiding unit 5, holding unit 22 that is provided below the optical component 14 and sucks and holds the above-described chip 1, and injection unit 23 that forms an air curtain by an inert gas around the chip 1 held by the holding unit 22, and these are integrally moved by moving unit 24.

The above-described moving unit 24 is configured to move the above-described bonding head 7 in a horizontal direction (X-Y direction) and raise and lower it in an up-down direction (Z direction) and further includes a rotating mechanism that rotates the above-described chip 1 along with the bonding head 7.

The above-described holding unit 22 includes transparent upper plate 25 and lower plate 26, and a tool attachment 27 provided on an undersurface of the above-described lower plate 26, and negative pressure supply unit 28 that supplies negative pressure to the holding unit 22 is connected to the holding unit 22.

The above-described upper plate 25 and lower plate 26 are formed of a transparent material such as quartz or glass capable of transmitting the laser light L from the laser light irradiation unit 4, and have substantially square shapes having larger areas than the above-described chip 1 as shown in FIG. 2.

The above-described upper plate 25 and lower plate 26 are held so as to be surrounded by a holder 22a, and are designed to allow the laser light L emitted by the above-described light irradiation means 4 to pass through the above-described upper plate 25 and lower plate 26 downward from above.

A spacer 29 that is provided in an endless shape along an outer peripheral edge is provided between the above-described upper plate 25 and lower plate 26, and thereby a negative pressure passage R that communicates with the above-described negative pressure supply unit 28 is formed between the upper plate 25 and the lower plate 26.

The above-described tool attachment 27 is formed of a transparent material such as quartz or glass capable of transmitting the laser light L, is provided on the undersurface of the above-described lower plate 26, and has a substantially square shape having a larger area than the above-described chip 1 as shown in FIG. 2.

Through-holes 26a and 27a are formed in the up-down direction in substantially central portions of the above-described lower plate 26 and tool attachment 27, and when the above-described chip 1 is located under the above-described through-holes 26a and 27a, the chip 1 is sucked by an undersurface of the tool attachment 27 by the negative pressure supplied to the above-described negative pressure passage R.

The above-described negative pressure supply unit 28 is controlled by the above-described control unit 8, and it is possible to suck and hold, and release the above-described chip 1 by controlling supply of the negative pressure.

The above-described injection unit 23 is composed of a frame 23a that surrounds an outer periphery further than the above-described holder 22a, and the frame 23a has a substantially U-shape in section in which an opening portion faces an inside.

Accordingly, a gas passage 23b that surrounds the above-described holder 22a in an endless shape is formed between the frame 23a and an outer peripheral surface of the above-described holder 22a, and gas supply unit 30 is connected to the gas passage 23b.

The above-described gas supply unit 30 supplies an inert gas such as nitrogen gas to prevent bonding defects due to oxidation from being caused when joining the above-described chip 1 and substrate 2. In order to reduce an oxide film on the solder that forms the bumps B, reducing gas such as hydrogen or formic acid may be mixed with the above-described inert gas.

In a lower portion of the above-described frame 23a, a slit S is formed in a space from the outer peripheral surface of the above-described holder 22a, this slit S communicates with the above-described gas passage 23b, and thereby injects the inert gas that is supplied into the above-described gas passage 23b toward a lower side.

Hereinafter, an operation of the bonding apparatus 3 having the above-described configuration will be described.: First, the control unit 8 moves the bonding head 7 to chip supply unit not illustrated by the above-described moving unit 24, and the bonding head 7 sucks and holds the above-described chip 1 on the above-described holding unit 22 by the negative pressure from the above-described negative pressure supply unit 28.

On the other hand, the control unit 8 supplies the above-described substrate 2 to a required position on the above-described bonding stage 6 by substrate supply unit not illustrated, and the bonding stage 6 sucks and holds the substrate 2.

Then, the heating unit provided in the bonding stage 6 heats the substrate 2, and thereby the substrate 2 is thermally expanded.

When the above-described bonding head 7 holds the above-described chip 1, the control unit 8 causes the first laser oscillator 4a of the laser light irradiation unit 4 to emit the first laser light L1.

Then, as shown in FIG. 4 (a), the first laser light L1 emitted by the first laser oscillator 4a is guided to the chip 1 held by the bonding head 7 along the first light guide path R1.

Specifically, the first laser light L1 guided by the above-described first optical fiber 11a passes through the above-described half mirror 12, thereafter, is reflected by the mirror 13 to be incident on the optical component 14, and is emitted to the chip 1 held by the holding unit 22 from above in the state in which it is shaped in a required shape.

When the chip 1 is irradiated with the first laser light L1 like this, the above-described chip 1 is heated by the first laser light L1, and the positions of the above-described electrodes la change due to thermal expansion, but since the first laser light L1 is set to the output power that does not melt the bumps B of the chip 1, it is possible to maintain the state in which the bumps B are formed on the chip 1.

By preheating the chip 1 like this, it is possible to reduce a thermal expansion difference between the chip 1 and the substrate 2 during bonding, and it is also possible to suppress deformations such as warping caused by a temperature difference when the chip 1 and the substrate 2 contact each other.

Next, the control unit 8 moves the bonding head 7 to photographing unit not illustrated by the above-described moving unit 24 while irradiating the above-described chip 1 with the first laser light L1, and the photographing unit photographs the undersurface of the chip 1 thermally expanded by preheat, and recognizes the positions of the electrodes la (bumps B) formed on the chip 1.

Since the positions of the electrodes la of the chip 1 are recognized in a same state as during bonding by photographing the thermally expanded chip 1 in this way, it is possible to more accurately align the electrodes 1a.

When the positions of the electrodes 1a of the chip 1 are recognized by the photographing unit, the control unit 8 rotates the chip 1 within a horizontal plane to align the positions of the electrodes 1a of the chip 1 with the positions of the electrodes 2a of the substrate 2 while moving the bonding head 7 to above the bonding stage 6 by the above-described moving unit 24.

Furthermore, the moving unit 24 positions the chip 1, which is held, above the bonding position of the chip 1 in the substrate 2 supported by the bonding stage 6 (for example, a position in which a gap between the bonding head 7 and the bonding stage 6 is 5 mm).

Here, the control unit 8 continues resonation of the first laser light L1 by the above-described laser oscillator 4a, and the chip 1 is caused to maintain a state of being preheated at a required temperature.

When the bonding head 7 positions the chip 1 above the bonding position in this way, the control unit 8 injects the inert gas downward from the above-described slit S by the above-described injection unit 23.

The injected inert gas forms the air curtain that surrounds the bonding position of the chip 1 sucked and held by the holding unit 22 and the above-described substrate 2, and prevents inflow of air from outside of the air curtain, whereby it is possible to prevent the bonding portions of the chip 1 and the substrate 2 from being oxidized.

Furthermore, the inert gas that flows in between the bonding head 7 and the bonding stage 6 fills the space between the above-described chip 1 and the substrate 2, and thereby expels oxygen that is previously present to outside.

When the space between the chip 1 and the substrate 2 is replaced by the inert gas in this way, the control unit 8 stops the first laser oscillator 4a of the above-described laser light irradiation unit 4 and causes the second laser oscillator 4b to emit the second laser light L2.

Then, as shown in FIG. 4 (b), the second laser light L2 emitted from the second laser oscillator 4b is guided in the second light guide path R2 by the light guiding unit 5, and is guided to the bonding head 7.

Specifically, the second laser light L2 emitted from the second laser oscillator 4b is guided in the above-described second light guide path R2, and is reflected by the above-described half mirror 12 at that time to thereby become coaxial with the above-described first light guide path R1, and is emitted to the chip 1 held by the bonding head 7.

The above-described second laser light L2 has higher power than the first laser light L1, and the whole of the chip 1 irradiated with the second laser light L2 is heated, whereby the bumps B formed on the electrodes la of the chip 1 are melted.

Then, the control unit 8 controls the above-described moving unit 24 to lower the bonding head 7 to bring the chip 1 into close contact with the substrate 2. Then, the control unit 8 stops resonation of the second laser light L2 from the second laser oscillator 4b, whereby the melted bumps B are cooled and solidified, and the chip 1 and the substrate 2 are bonded.

According to the above-described embodiment, the chip 1 is irradiated with the first laser light L1 with low output power to preheat the whole of the chip 1 to a degree that does not melt the bumps B in FIG. 4(a), and thereafter, the chip 1 is irradiated with the second laser light L2 to be heated as shown in FIG. 4(b), whereby even the large chip 1 can be efficiently bonded to the substrate 2.

Furthermore, when the chip 1 is heated by the laser light, the positions of the electrodes 1a of the chip 1 are slightly misaligned due to thermal expansion, but by heating the chip 1 by the first laser light L1, it is possible to photograph the chip 1 in the state of being thermally expanded, and it is possible to accurately bond the chip 1 to the substrate 2.

In the present embodiment, since the chip 1 is preheated by the first laser light L1 while the positions of the electrodes la of the chip 1 are recognized, if the chip 1 is irradiated with the second laser light L2 in the state in which it is positioned in the bonding position, it is possible to quickly heat the chip 1 to the bondable temperature, and it is possible to efficiently perform bonding.

In particular, in the case of the large chip 1, heating it takes time, and therefore, it is possible to perform efficient bonding by preheating it with the above-described first laser light L1.

Note that if the positions of the first laser oscillator 4a and the second laser oscillator 4b are swapped, and the dielectric multilayer film of the half mirror 12 that composes the above-described light guiding unit 5 is changed in the above-described embodiment, the first and second light guide paths R1 and R2 can be set so that the first laser light L1 is reflected by the half mirror 12, and the second laser light L2 passes through the half mirror 12.

Furthermore, in the above-described embodiment, after the chip 1 is preheated by the first laser light L1, resonation of the first laser light L1 is stopped, and thereafter the second laser light L2 is emitted to heat the chip 1 to bring it into the state in which it can be bonded.

On the other hand, even after preheat of the chip 1 is completed, the state in which the first laser light L1 is emitted may be maintained, the second laser light L2 may be emitted by the second laser oscillator 4b in this state, and the first laser light L1 and the second laser light L2 may be superimposed to irradiate the above-described chip 1 with them.

In this case, it is possible to make the output power of the second laser light L2 emitted by the second laser oscillator 4b lower than the above-described embodiment, and it is also conceivable, for example, to set the output power of the second laser light L2 to output power that does not melt the bumps B for itself but is higher than that of the first laser light L1, and melt the bumps B by total output power of the first laser light L1 and the second laser light L2.

Furthermore, in the above-described embodiment, the laser light irradiation unit 4 includes the first and second laser oscillators 4a and 4b, but third and fourth laser oscillators are provided, and the light guiding unit can switch to light guide paths of the third and fourth laser lights respectively.

In this case, by making the output power and the wavelength different for each of the laser oscillators, it becomes possible to perform bonding by using appropriate laser light according to a size, material and the like of the chip.

### REFERENCE SIGNS LIST

1 chip
2 substrate
3 bonding apparatus
4 laser light irradiation unit
4a first laser oscillator
4b second laser oscillator
5 light guiding unit
7 bonding head
12 half mirror
14 optical component
22 holding unit
B bump
L1 first laser light
L2 second laser light

1. A bonding apparatus comprising: a laser light irradiation unit that emits laser light; a holding unit that holds a chip in which a bump is formed on an undersurface; and a light guiding unit that guides the laser light to a top surface of the chip held by the holding unit,
wherein the laser light irradiation unit has a first laser oscillator that emits a first laser light set to output power that does not melt the bump, and a second laser oscillator that emits a second laser light set to higher output power than the first laser light, and includes a control unit that controls the first laser oscillator and the second laser oscillator, and
wherein the control unit is configured to cause the first laser oscillator to emit the first laser light to preheat the chip, and thereafter cause the second laser oscillator to emit the second laser light, or cause the first and second laser oscillators to emit the first laser light and the second laser light, so as to heat the chip to a bondable temperature.

2. The bonding apparatus according to claim 1,
wherein the output power of the second laser light of the second laser oscillator is set to output power that melts the bump of the chip, and
when heating the chip to the bondable temperature, the control unit causes only the second laser oscillator to emit the second laser light.

3. The bonding apparatus according to claim 1,
wherein the light guiding unit includes a half mirror that transmits either one of the first laser light or the second laser light, and reflects the other, and
either one of the first laser light or the second laser light is reflected by the half mirror to be thereby made coaxial with an optical axis of the other of the first laser light or the second laser light that passes through the half mirror, and thereafter is guided to a top surface of the chip.
